(19) United States
(12) Patent Application Publication
(10) Pub. No.: US 2025/0204056 A1
(43) Pub. Date: Jun. 19, 2025

(54) MANUFACTURING METHOD FOR MANUFACTURING A PHOTOVOLTAIC ELEMENT

(71) Applicant: Valoe Oyj, MIKKELI (FI)

(72) Inventors: Tuukka SAVISALO, MIKKELI (FI); Hannu VÄISÄNEN, MIKKELI (FI); Henri AUVINEN, MIKKELI (FI); Kimmo KORHONEN, MIKKELI (FI); Matti HYÖTYLÄINEN, MIKKELI (FI); Tuomas VANHANEN, MIKKELI (FI)

(21) Appl. No.: 18/845,284

(22) PCT Filed: Mar. 9, 2023
(86) PCT No.: PCT/FI2023/050129

§ 371 Date: Sep. 9, 2024

(30) Foreign Application Priority Data
Mar. 9, 2022 (FI) 20225205

(51) Int. Cl. H10F 19/80; H10F 19/90

(52) U.S. Cl. CPC H10F 19/807; H10F 19/902

(57) ABSTRACT

The application is directed to a method for the manufacture of a photovoltaic element that comprises placing a first encapsulation layer on the first support plate to protect the photovoltaic cells and forming an active layer of the photovoltaic cells connected to electrical conductors; placing a second encapsulation layer on top of the active layer to protect the photovoltaic cells; placing a second support plate on top of the second encapsulation layer to form a photovoltaic structure such that the first and second encapsulation layers form a continuous encapsulation between the first and second support plates to protect the active layer; and removing at least one support plate comprising removable material from the encapsulation such that an outer surface of the flexible photovoltaic element used in a manufacture of a non-planar photovoltaic module is formed from an outer surface of the encapsulation exposed by the partially removed support plate.

### TECHNICAL FIELD

The application concerns in general a manufacturing method for manufacturing a photovoltaic element.

### BACKGROUND

The manufacture of a traditional frame-mounted planar photovoltaic module used in photovoltaic systems starts by placing the bottom encapsulation layer, intended to protect the active layer, on top of a lower support plate made of rigid plastic.

The active layer containing the photovoltaic cells is formed by placing a conductive layer containing the electrical conductors on top of the bottom encapsulation layer and, on top of that, a middle encapsulation layer containing the connections of the conductors and cells. Finally, the cells are placed on top of the middle encapsulation layer so that the cells and the conductors are connected to each other.

On top of the active layer there is formed a top encapsulation layer to protect it and finally, on top of that, a top support plate made of glass. The stacked structure is heated up to make the encapsulation layers to form a continuous encapsulation between the plastic and glass support plates to protect the active layer. The module is finished by mounting it in module frames and making the conductors ready for connection, so that the module with back-contact cells can be connected to the system.

### SUMMARY

One objective of the invention is to solve the problems of the known technology and to obtain a flexible photovoltaic element which makes it possible to manufacture a photovoltaic module with front or back connection (front or back contact) of solar cells for non-planar (three-dimensional) surface structures of means of transport, buildings or other types of structures.

One objective of the invention is achieved by a manufacturing method and a photovoltaic element according to the independent claims.

Embodiments of the invention comprise a manufacturing method and a photovoltaic element according to the independent claims.

In a manufacturing method for manufacturing a photovoltaic element, a first encapsulation layer for protecting photovoltaic cells are placed on top of a first support plate and an active layer comprising the photovoltaic cells connected to electrical conductors is formed. The method further comprises placing a second encapsulation layer on top of the active layer to protect the photovoltaic cells and placing a second support plate on top of the second encapsulation layer to form the photovoltaic structure such that the first and second encapsulation layers form a continuous encapsulation between the first and second support plates to protect the active layer. The method further comprises removing at least one support plate comprising removable material from the encapsulation such that an outer surface of the flexible photovoltaic element used in a manufacture of a non-planar photovoltaic module is formed from an outer surface of the encapsulation exposed by the at least partially removed support plate.

A photovoltaic element for use in the manufacture of the a non-planar photovoltaic module according to the manufacturing method described above comprises the active layer comprising the photovoltaic cells connected to the electrical conductors and the continuous encapsulation protecting the active layer. The outer surface of the encapsulation forming at least partially the outer surface of the flexible photovoltaic element.

### BRIEF DESCRIPTION OF THE FIGURES

In the detailed description of the figures, exemplary embodiments of the invention are described in more detail with reference to the following figures:

FIG. 1 shows a flexible photovoltaic element and its detail in a basic cross-sectional view

FIG. 2 shows the manufacturing process of a photovoltaic element by means of a flow diagram and basic cross-sectional drawings

FIG. 3 shows a non-planar photovoltaic module

### DETAILED EXPLANATION OF THE FIGURES

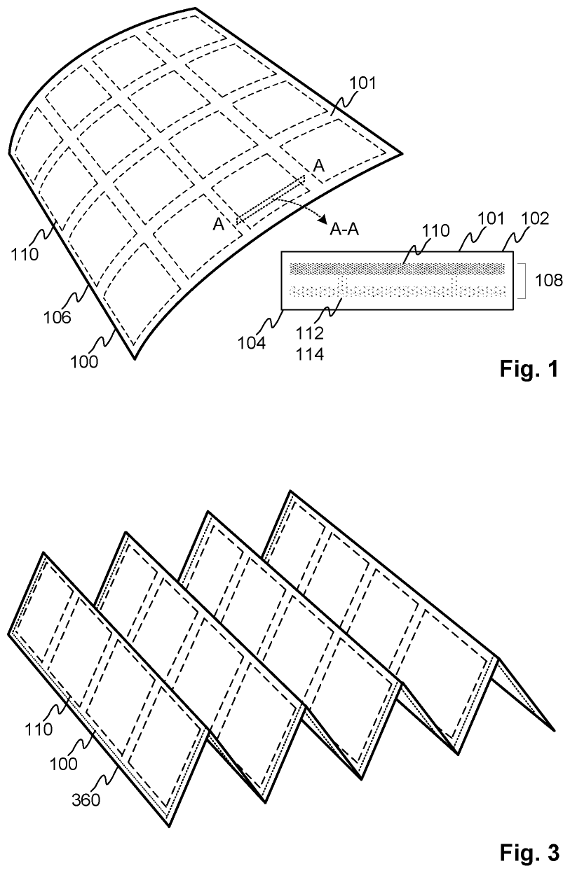

FIG. 1 shows a flexible photovoltaic element 100 comprising an encapsulation 106 formed by a first encapsulation layer 102 and a second encapsulation layer 104 forming its outer surface 101, the purpose of the encapsulation 106 being to protect the active layer 108 of the element.

The element 100 or part thereof can be bent into a convex, concave, wavy, cylindrical or any other non-planar shape due to the flexible structure of the element 100.

Each encapsulation layer 102, 104 comprises elastomers suitable for encapsulation, e.g. ethylene vinyl acetate (EVA), silicone or polyurethane (PU) based materials, such that the encapsulation layers 102, 104 together form a continuous encapsulation 106 protecting the active layer 108.

The active layer 108 comprises solar power cells (photovoltaic cells) 110 exploiting the photoelectric effect, which allow the generation of electrical energy (electricity) by means of the solar radiation they receive, and electrical conductors 112 and connections 114 formed on the cells 110 by means of which the cells 110 are connected to electronics (not shown) for converting the electricity generated in the cells 110 into a form that can be used in electrical equipment or stored in batteries.

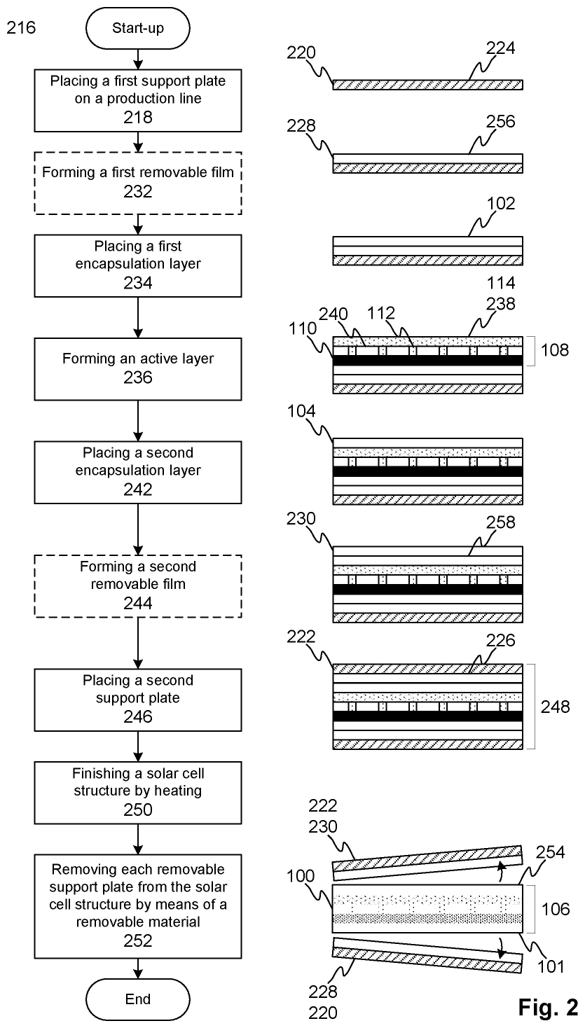

FIG. 2 shows the manufacturing method 216 of the element 100 of the preceding figure in steps.

In step 218, a first removable support plate (bottom support plate) 220 is placed on the production line of the elements 100, intended to support the element 100 to be manufactured during the manufacturing process, before being removed later to finish the element 100.

The support plate 220, as well as a second, likewise removable, support plate (top support plate) 222 to be subsequently installed, comprises removable material to facilitate the removal of the respective support plate 220, 222 from the element 100 to be finished. The removable material comprises a so-called low surface-active material (non-stick material), i.e. a material with low adhesion to another surface. The removable material comprises a fluorine-based plastic (fluoropolymer), e.g. polytetrafluoroethylene (PTFE, Teflon) or ethylene tetrafluoroethylene (ETFE).

Unlike in the figure, the support plate 220, 222 may be made of the removable material, or alternatively, as shown in the figure, the support plate 220, 222 comprising the removable material may be made of a material other than the removable material, e.g. glass, plastic, metal, such as aluminium, or ceramic material.

If the support plate 220, 222 is made of a material other than the removable material, the surface 224, 226 of the support plate 220, 222 facing the active layer 108 may, contrary to the figure, have a removable film 228, 230 pre-formed on it by coating, e.g. by spraying, dipping or painting, which removable film 228, 230, comprising the removable material, is intended to be placed between the support plate 220, 222 and an encapsulation layer 102, 104 (encapsulation 106) facing it for the removal of the respective support plate 220, 222.

Regardless of whether support plates 220, 222 made of the removable material or support plates 220, 222 coated with the removable material are used, the upper surface 224 of support plate 220 and the lower surface 226 of support plate 222 will face the encapsulation 106.

Alternatively, if the support plate 220, 222 is made of a material other than the removable material and does not have a pre-formed removable film 228, 230 on its surface 224, 226, then, in step 232, a separate removable film 228 made of a removable material is formed, as shown, on the upper surface 224 of the support plate 220, and subsequently also against the lower surface 226 of the support plate 222, by placing the removable film 228 on the support plate 220 so that it is positioned between the support plate 220 and the adjacent encapsulation layer 102. The upper surface 256 of the removable film 228 and the lower surface 258 of the subsequently inserted removable film 230 are thereby positioned against the encapsulation 106.

In step 234, in contrast to the drawing, the bottom encapsulation layer 102 for protecting the cells 110, conductors 112 and connections 114 of the active layer 108 is placed directly on top of the support plate 220, if the support plate 220 is made of a removable material. Alternatively, in step 234, the bottom encapsulation layer 102 is placed over the support plate 220 and the coated or separate removable film 228 as shown, if the support plate 220 is not of a removable material.

In step 236, an active layer 108 comprising the (back-contact) cells 110 connected to the conductors 114 is formed, in contrast to the figure, by forming a conductive layer 238 comprising the conductors 114 over the encapsulation layer 102, placing a third, middle encapsulation layer 240 comprising the connections 112 between the conductors 114 and the cells 110 over the conductive layer 238, and then placing the cells 110 over the encapsulation layer 240 such that a connection 112 is formed between each cell 110 and conductor 114 on the back side of the cell 110.

Alternatively, in step 236, an active layer 108 comprising the (back-contact) cells 110 connected to the conductors 114 is formed as shown by placing the cells 110 on top of the encapsulation layer 102, then placing the encapsulation layer 240 comprising the connections 112 between the conductors 114 and the cells 110 on top of the cells 110 (on the back side), and finally forming a conductive layer 238 comprising the conductors 114 on top of the encapsulation layer 240.

Alternatively, the active layer 108 may be formed such that the connections 112 and conductors 114 are implemented on the front side of the cells 110 as a front connection.

In step 242, a top encapsulation layer 104 for protecting the cells 110, conductors 112 and connections 114 is placed over the formed active layer 108 so that the encapsulation layers 102, 104 can form a continuous encapsulation 106 protecting the active layer 108.

In step 244, a separate removable film 230 is formed (placed) on top of encapsulation layer 104 (encapsulation 106) as shown in the figure, if the support plate 220 is not of a removable material and does not have a pre-coated removable film 230.

In step 246, a support plate 222 is placed directly on top of the encapsulation layer 104 if the support plate 222 is made of a removable material or has a removable film 230 coated like the support plate 220, whereby the support plates 220, 222 and the interposed structural layers 102, 110, 240, 238, 104 form a solar cell structure 248, wherein the encapsulation layers 102, 104 form a continuous encapsulation 106 between the support plates 220, 222 protecting the active layer 108.

Alternatively, in step 246, a support plate 222 is placed over the encapsulation layer 104 and the separate removable film 228 as shown in the figure, if a separate removable film 230 has been placed over the encapsulation layer 104 in step 244, in which case the support plates 220, 222 and the structural layers 228, 102, 110, 240, 238, 104, 230 between them form a solar cell structure 248.

Once the structure 248 is formed, in step 250 it is finished by heating and pressing (laminating) along the structure 248 before the mechanical removal of each of the support plates 102, 104 intended to be removed such that the encapsulation layers 102, 104 together with the encapsulation layer 240 are permanently (solidly) attached to one another around the cells 110, conductors 112 and connections 114, forming a laminated encapsulation 106 protecting the active layer 108, which cannot be disassembled without breaking parts 110, 112, 114 of the active layer 108.

In step 252, the element 100 is finished by removing at least a portion of one or both of the support plates 220, 222 from the encapsulation 106 such that the outer surface 101 of the flexible element 100 is at least partially formed by the outer surface 254 of the encapsulation 106 exposed by the removal of each support plate 220, 222 or portion thereof.

Alternatively, in step 252, at least one of the support plates 220, 222 is completely removed from the encapsulation 106, or at least one of the support plates 220, 222 is completely removed and a portion of the other support plate 220, 222 is removed, or, as shown, both of the support plates 220, 222 are completely removed, whereby the outer surface 101 of the element 100 comprises the outer surface 254 of the encapsulation 106 exposed by the removal of each support plate 220, 222 or portion thereof.

Removal of the support plate 220, 222 or portion thereof is accomplished by removing the support plate 220, 222 made of or coated with a removable material from the outer surface 254 of the encapsulation 106. Alternatively, if a removable film 228, 230 is used between the support plates 220, 222, the removal of the support plate 220, 222 is accomplished by removing all or part of the removable film 228, 230 of the support plate 220, 222 from the outer surface 254 of the encapsulation 106, whereby the support plate 220, 222 is removed from the outer surface 254 at the point corresponding to the removed removable film 228, 230 or portion thereof.

Regardless of whether support plates 220, 222 made of a removable material, support plates 220, 222 coated with a removable material or removable films 228, 230 between the support plates 220, 222 and the encapsulation 106 are used, the shape of the surface 224, 226, 256, 258 of the removable material against the encapsulation 106 determines the shape of the outer surface 101 of the element 100. The outer surface 254 of the encapsulation 106 thus forms at least partially or entirely, depending on the removal of the support plates 220, 222, the outer surface 101 of the flexible element 100.

The element 100 reaches its maximum flexibility when both support plates 220, 222 are completely removed, whereby the outer surface 254 of the encapsulation 106 completely forms the outer surface 101 of the element 100 and the element 100 can be adapted to the application in the form required by its surface contours. By leaving portions of the support plate 220, 222 or one of the support plates 220, 222 entirely on the outer surface 254 of the encapsulation 106, it is possible to adjust the flexibility of the element according to the needs of the application, if the application requires stiffness of the element structure 100 for some reason.

FIG. 3 shows a non-planar photovoltaic module 360 manufactured using one of the flexible elements 100 shown in the previous figures.

The module 360 can be manufactured in virtually any non-planar shape, e.g. convex, concave, pleated or wavy as shown, making it mountable on non-planar surface structures of e.g. vehicles, such as cars, vans, trucks, trains, aircraft, or buildings or various other structures, such that the module 360 is connectable by electrical connectors (not shown) to the electrical system of the installation site to generate electricity via cells 110.

Only some exemplary embodiments of the invention have been described above. Naturally, the principle according to the invention can be modified within the scope of protection defined by the claims, e.g. with regard to implementation details and fields of application.

1. A manufacturing method for manufacturing a photovoltaic element, comprising
placing a first encapsulation layer on a first support plate to protect photovoltaic cells,
forming an active layer comprising the photovoltaic cells connected to electrical conductors,
placing a second encapsulation layer on top of the active layer to protect the photovoltaic cells, and
placing a second support plate on top of the second encapsulation layer to form a photovoltaic structure such that the first and second encapsulation layers form a continuous encapsulation between the first and second support plates to protect the active layer,
wherein the manufacturing method further comprises removing at least one support plate comprising removable material from the encapsulation such that an outer surface of the flexible photovoltaic element used in a manufacture of a non-planar photovoltaic module is formed by an outer surface of the encapsulation exposed by the at least partially removed support plate.

2. The manufacturing method according to claim 1, comprising removing both the first and second support plates comprised of the removable material from the encapsulation such that the outer surface of the photovoltaic element is formed by the outer surface of the encapsulation exposed by the removed support plates.

3. The manufacturing method according to claim 1, further comprising heating the photovoltaic structure after the attachment of the second support plate for finishing the photovoltaic structure prior to a mechanical removal of each support plate intended to be removed.

4. The manufacturing method according to claim 1, wherein the removable material is made of fluorine-based plastic.

5. The manufacturing method according to claim 4, wherein the fluorine-based plastic comprises polytetrafluoroethylene or ethylenetetrafluoroethylene.

6. The manufacturing method according to claim 1, further comprising forming a removable film comprised of a removable material between each support plate to be removed and the encapsulation layer facing the support plate to be removed, for the removal of the respective support plate.

7. The manufacturing method according to claim 1, wherein the removal of each removable support plate is accomplished by removing a removable film of the removable support plate from the outer surface of the encapsulation.

8. The manufacturing method according to claim 7, wherein the removable film comprises a separate removable film interposed between each removable support plate and the encapsulation layer facing it.

9. The manufacturing method according to claim 7, wherein the removable film comprises a removable material coated on an inner surface of each removable support plate facing the encapsulation layer.

10. The manufacturing method according to claim 1, wherein each removable support plate having a supportive function in the manufacture of the photovoltaic element is made of glass, plastic, metal, or ceramic material.

11. The manufacturing method according to claim 1, wherein each removable support plate is formed of a removable material.

12. The manufacturing method according to claim 1, wherein a shape of a surface of the removable material facing the encapsulation determines a shape of an outer surface of the photovoltaic element.

13. The manufacturing method according to claim 1, wherein the formation of the active layer comprises forming a conductive layer comprising the electrical conductors on top of the first encapsulation layer, placing a third encapsulation layer comprising the electrical connections between the electrical conductors and the photovoltaic cells on top of the conductive layer, and placing the photovoltaic cells on top of the third encapsulation layer.

14. The manufacturing method according to claim 1, wherein the formation of the active layer comprises placing the photovoltaic cells on top of the first encapsulation layer, placing a third encapsulation layer comprising electrical connections between the electrical conductors and the photovoltaic cells on top of the photovoltaic cells, and forming a conductive layer comprising the electrical conductors on top of the third encapsulation layer.

15. A photovoltaic element manufactured by the manufacturing process according to claim 1 for a manufacture of a non-planar photovoltaic module, comprising an active layer comprising photovoltaic cells connected to the electrical conductors and the continuous encapsulation protecting the active layer, wherein the outer surface of the encapsulation forming at least partially the outer surface of the flexible photovoltaic element.
